(19) United States
(12) Patent Application Publication
(10) Pub. No.: US 2023/0361251 A1
(43) Pub. Date: Nov. 9, 2023

(54) SEMICONDUCTOR DEVICE INCLUDING PASSIVATION LAYER AND METHOD OF FABRICATING ELECTRONIC APPARATUS

(71) Applicant: Samsung Electronics Co., Ltd., Suwon-si (KR)

(72) Inventors: Minchul YU, Suwon-si (KR); Seogwoo HONG, Yongin-si (KR); Kyungwook HWANG, Seoul (KR); Junsik HWANG, Hwaseong-si (KR); Dongkyun KIM, Suwon-si (KR); Hyunjoon KIM, Seoul (KR)

(73) Assignee: Samsung Electronics Co., Ltd., Suwon-si (KR)

(21) Appl. No.: 17/900,193

(22) Filed: Aug. 31, 2022

(30) Foreign Application Priority Data
May 6, 2022 (KR) 10-2022-0056247

(51) Int. Cl. H01L 33/44; H01L 33/00

(52) U.S. Cl. CPC H01L 33/44; H01L 33/005

(57) ABSTRACT

Provided are a semiconductor device including a passivation layer and a method of fabricating an electronic apparatus including the semiconductor device. The semiconductor device includes a semiconductor device layer including at least one electrode provided at an upper portion thereof and a passivation layer at least partially covering the at least one electrode.

### CROSS-REFERENCE TO RELATED APPLICATION

This application is based on and claims priority under 35 U.S.C. § 119 to Korean Patent Application No. 10-2022-0056247, filed on May 6, 2022, in the Korean Intellectual Property Office, the disclosure of which is incorporated by reference herein in its entirety.

### BACKGROUND

### 1. Field

The disclosure relates to a semiconductor device including a passivation layer and a method of fabricating an electronic apparatus

### 2. Description of Related Art

Recently, a micro light emitting diode (LED) display apparatus using a micro-unit LED chip as a pixel has been developed. In fabricating a display apparatus using micro-unit LED chips, attempts to use a fluid self-assembly (FSA) method have increased. However, in the transfer process of the LED chips of the FSA method, electrodes are transferred in an exposed state without a passivation layer, and thus, the electrodes may be physically and chemically damaged by the external environment.

### SUMMARY

Provided are a semiconductor device including a passivation layer and a method of fabricating an electronic apparatus.

Additional aspects will be set forth in part in the description which follows and, in part, will be apparent from the description, or may be learned by practice of the presented embodiments of the disclosure.

According to an aspect of the disclosure, a semiconductor device may include a semiconductor device layer including at least one electrode provided on at upper portion thereof and a passivation layer at least partially covering the at least one electrode.

The passivation layer may include a material that does not chemically react with an electrolyte.

The passivation layer may include parylene.

The semiconductor device layer may further include a first semiconductor layer doped with impurities of a first conductivity type, a light emitting layer provided on the first semiconductor layer, and a second semiconductor layer provided on the light emitting layer and doped with impurities of a second conductivity type. The at least one electrode may be provided on the second semiconductor layer.

The at least one electrode may include a first electrode electrically connected to the first semiconductor layer and a second electrode electrically connected to the second semiconductor layer.

The passivation layer may cover at least one of the first electrode and the second electrode.

The semiconductor device may include an insulating layer provided between the second semiconductor layer and the at least one electrode.

The first semiconductor layer and the second semiconductor layer may include an n-type semiconductor layer and a p-type semiconductor layer, respectively.

The first semiconductor layer and the second semiconductor layer may include a p-type semiconductor layer and an n-type semiconductor layer, respectively.

The semiconductor device may include one of a laser device, a detector device, a sensor device, a power device, and a transistor device.

According to an aspect of the disclosure, a method of fabricating an electronic apparatus may include forming a plurality of semiconductor device layers on a semiconductor substrate, each of the plurality of semiconductor device layers including at least one electrode, forming a passivation layer on the plurality of semiconductor layers, removing a partial region of the passivation layer such that the passivation layer remains on an upper portion of the plurality of semiconductor device layers, separating the plurality of semiconductor device layers from the semiconductor substrate, transferring the plurality of semiconductor device layers to a transfer substrate, removing the passivation layer, and transferring the plurality of semiconductor device layers on the transfer substrate to an electronic apparatus substrate including a driving circuit.

The separating of the plurality of semiconductor device layers from the semiconductor substrate may be performed by immersing the semiconductor substrate in a potassium hydroxide (KOH) solution.

The plurality of semiconductor device layers may be transferred to the transfer substrate by a fluidic self-assembly (FSA) method.

The passivation layer may include parylene.

The passivation layer may be removed by using an oxygen (02) plasma treatment.

The plurality of semiconductor device layers may include a first semiconductor layer doped with impurities of a first conductivity type, a light emitting layer provided on the first semiconductor layer, and a second semiconductor layer provided on the light emitting layer and doped with impurities of a second conductivity type. The at least one electrode may be provided on the second semiconductor layer.

The at least one electrode may include a first electrode electrically connected to the first semiconductor layer and a second electrode electrically connected to the second semiconductor layer.

The passivation layer may cover at least one of the first electrode and the second electrode.

The first semiconductor layer and the second semiconductor layer may include an n-type semiconductor layer and a p-type semiconductor layer, respectively.

The first semiconductor layer and the second semiconductor layer may include a p-type semiconductor layer and an n-type semiconductor layer, respectively.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view of a semiconductor device according to an embodiment;

FIG. 2 is a cross-sectional view of a semiconductor device according to an embodiment;

FIG. 3 is a cross-sectional view of a semiconductor device according to an embodiment;

FIG. 4 is a cross-sectional view of a semiconductor device according to an embodiment;

FIGS. 5A, 5B, 5C, 5D, 5E, and 5F are diagrams of a method of fabricating a semiconductor device, according to an embodiment; and

FIGS. 6A, 6B, and 6C are diagrams of a method of fabricating an electronic apparatus, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. Like reference numerals in the drawings denote like components, and sizes of components in the drawings may be exaggerated for convenience of explanation. Embodiments described below are only exemplary and various changes in form and details may be made therein.

Hereinafter, the description “upper portion” or “upper” may include not only those directly on, under, left, and right in contact, but also those directly above, below, left, and right in non-contact. Singular expressions include plural expressions unless they are explicitly and differently specified in context. In addition, when a portion includes a component, a case may mean further including other components without excluding other components unless otherwise described.

The use of the term “above” and similar indicative terms may correspond to both singular and plural. When there is no explicit description or contrary description of operations constituting a method, these operations may be performed in an appropriate order, and may not be necessarily limited to the described order.

In addition, the terms “ . . . part” and “module” as used in the disclosure refer to a unit that performs at least one function or action, which may be implemented in hardware or software, or as a combination of hardware and software.

Connections of lines between components or connection members illustrated in the drawings exemplarily represent functional connection and/or physical or circuitry connections, and in a real apparatus, may be implemented by replaceable or additional various functional connections, physical connections, or circuitry connections.

The use of all examples or example terms is simply for describing a technical idea in detail, and the scope of the disclosure is not limited by these examples or example terms unless limited by the claims.

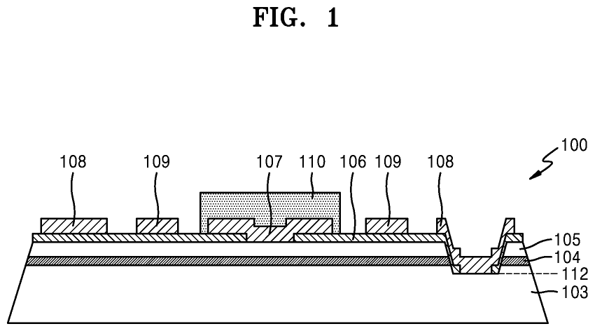

FIG. 1 is a cross-sectional view of a semiconductor device 100 according to an embodiment.

Referring to FIG. 1, the semiconductor device 100 may include a semiconductor device layer and a passivation layer 110 on the semiconductor device layer. FIG. 1 exemplarily illustrates a case in which the semiconductor device layer is a light emitting device.

The semiconductor device layer may include a first semiconductor layer 103, a light emitting layer 104 on the first semiconductor layer 103, a second semiconductor layer 105 on the light emitting layer 104, and at least one electrode on the second semiconductor layer 105.

The first semiconductor layer 103 and the second semiconductor layer 105 may include, for example, a Group III-V or Group II-VI compound semiconductor. The first semiconductor layer 103 and the second semiconductor layer 105 may provide electrons and holes to the light emitting layer 104. To this end, the first semiconductor layer 103 and the second semiconductor layer 105 may be doped with impurities of electrically opposite types. The first semiconductor layer 103 may be doped with impurities of a first conductivity type, and the second semiconductor layer 105 may be doped with impurities of a second conductivity type. For example, the first semiconductor layer 103 may be doped with n-type impurities, and the second semiconductor layer 105 may be doped with p-type impurities. In addition, the first semiconductor layer 103 may also be doped with p-type impurities, and the second semiconductor layer 105 may also be doped with n-type impurities.

The light emitting layer 104 may have a quantum well structure, in which a quantum well is between barriers. Electrons and holes provided by the first semiconductor layer 103 and the second semiconductor layer 105 may be recombined in the quantum well in the light emitting layer 104, and may generate light. A wavelength of light generated in the light emitting layer 104 may be determined according to an energy bandgap of a material constituting the quantum well in the light emitting layer 104. The light emitting layer 104 may include only one quantum well, but may include a multi-quantum well (MQW) structure, in which a plurality of quantum wells and a plurality of barriers are alternately arranged. A thickness of the light emitting layer 104 or the number of quantum wells in the light emitting layer 104 may be appropriately selected in consideration of a driving voltage, the light emitting efficiency, or the like of the semiconductor device 100.

At least one electrode may be on an upper surface of the second semiconductor layer 105. The at least one electrode may include a metal material having good conductivity. The at least one electrode may include a first electrode 108 and a second electrode 107 on the second semiconductor layer 105. In this case, the first and second electrodes 108 and 107 may be on an upper surface of the semiconductor device 100. An insulating layer 106 may be on the upper surface of the second semiconductor layer 105, and the first and second electrodes 108 and 107 may be on the insulating layer 106.

The first electrode 108 may be electrically connected to the first semiconductor layer 103. To electrically connect the first electrode 108 to the first semiconductor layer 103, a via hole 112 may be formed to penetrate the second semiconductor layer 105 and the light emitting layer 104, and the first electrode 108 may contact the first semiconductor layer 103 via the via hole 112. The insulating layer 106 may extend to surround sidewalls of the via hole 112. In other words, a portion of the second semiconductor layer 105 and a portion of the light emitting layer 104 exposed by the via hole 112 may be covered by the insulating layer 106. The first electrode 108 may extend from an upper surface of the insulating layer 106 to an upper surface of the first semiconductor layer 103 exposed via the via hole 112, and contact the first semiconductor layer 103 via the via hole 112.

The second electrode 107 may be electrically connected to the second semiconductor layer 105. The second electrode 107 may contact the upper surface of the second semiconductor layer 105 exposed via the insulating layer 106. In this case, a portion of the second electrode 107 may further extend from the upper surface of the insulating layer 106 in a lateral direction.

When the first and second semiconductor layers 103 and 105 include n-type and p-type semiconductor layers, respectively, the first and second electrodes 108 and 107 may include n-type and p-type electrodes, respectively. In addition, when the first and second semiconductor layers 103 and 105 include p-type and n-type semiconductor layers, respectively, the first and second electrodes 108 and 107 may include p-type and n-type electrodes, respectively.

A bonding spread prevention wall 109 may be further arranged between the first electrode 108 and the second electrode 107 on the upper surface of the insulating layer 106. The bonding spread prevention wall 109 may prevent a short circuit from occurring due to a bonding material, for example, a solder bump, spreading between the first electrode 108 and the second electrode 107, when, in a process of fabricating an electronic apparatus to be described below, the first electrode 108 and the second electrode 107 of the semiconductor device 100 are bonded to corresponding electrode pads on a driving substrate of the electronic apparatus. The bonding spread prevention wall 109 may have a shape protruding above the upper surface of the insulating layer 106. In this case, a thickness of the bonding spread prevention wall 109 may be less than or equal to thicknesses of the first and second electrodes 108 and 107. In addition, the bonding spread prevention wall 109 may include an electrically insulating material.

The passivation layer 110 may be on the semiconductor device layer. The passivation layer 110 may cover the second electrode 107 on the upper surface of the second semiconductor layer 105. In this case, the passivation layer 110 may prevent physical and chemical damages to the second electrode 107, which may occur during a transfer process of the semiconductor device by using a fluidic self-assembly (FSA) method to be described later.

In a process of aligning the semiconductor device to the transfer substrate by using an FSA method, electrodes may be physically damaged due to scratch by an external pressure or due to being peeled off, and when the electrodes are exposed to an electrolyte for a long time, a galvanic corrosion phenomenon due to a potential difference may occur, and a chemical damage may occur where portions of the electrodes are peeled off. In the present embodiment, the passivation layer 110 may cover the second electrode 107 of the semiconductor device layer, and thus, physical and chemical damages of the second electrode 107 may be prevented.

The passivation layer 110 may include a material that does not chemically react with an electrolyte. In addition, the passivation layer 110 may easily form a pattern, and in fabricating the semiconductor device 100, may include a material, that is not damaged by a solution (for example, a potassium hydroxide (KOH) solution or the like) used in a chemical lift-off process. In addition, after the transfer process of the semiconductor device 100, the passivation layer 100 may include a material, that is easily removed for bonding. The passivation layer 110 may include, for example, parylene. However, the embodiment is not limited thereto.

To easily align the semiconductor device 100 by using an FSA method, the semiconductor device 100 may have a shape, in which a diameter or width is greater than a thickness. In particular, a diameter or width of the first semiconductor layer 103 may be greater than the thickness of the semiconductor device 100. For example, the diameter or width of the first semiconductor layer 103 may be greater than the thickness of the semiconductor device 100 by one time, or two times or more, or five times or more. In this case, a size, that is, the diameter or width of the semiconductor device 100 may be defined as the diameter or width of the first semiconductor layer 103. Accordingly, the size, that is, the diameter or width of the semiconductor device 100 may be, for example, in a range of about 1 μm to about 100 μm, or in a range of about 5 μm to about 50 μm.

According to an embodiment, the semiconductor device 100 may have an inclined side surface such that the diameter or width of the first semiconductor layer 103 is greater than diameters or widths of the second semiconductor layer 105 and the insulating layer 106. For example, the diameter or width of the second semiconductor layer 105 may be about 0.7 times or more and less than about 1 time, or about 0.8 times or more and about 0.95 times or less of the diameter or width of the first semiconductor layer 103. Accordingly, an area of the first semiconductor layer 103 may be greater than areas of the second semiconductor layer 105 and the insulating layer 106. In addition, the diameter or width of the second semiconductor layer 105 of the semiconductor device 100 may also be greater than the thickness of the semiconductor device 100.

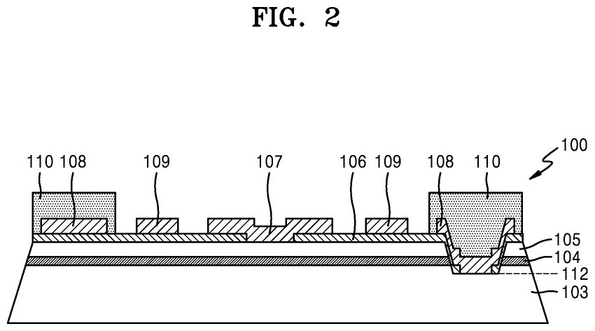

FIG. 2 is a cross-sectional view of the semiconductor device 100 according to an embodiment. The semiconductor device 100 illustrated in FIG. 2 may be the same as the semiconductor device 100 illustrated in FIG. 1, except that the passivation layer 110 covers the first electrode 108.

Referring to FIG. 2, the passivation layer 110 may cover the first electrode 108. The passivation layer 110 may prevent physical and chemical damages to the first electrode 108. In addition, the passivation layer 110 may also protect side well portions of the light emitting layer 104, by covering the sidewalls of the via holes 112 penetrating the second semiconductor layer 105 and the light emitting layer 104.

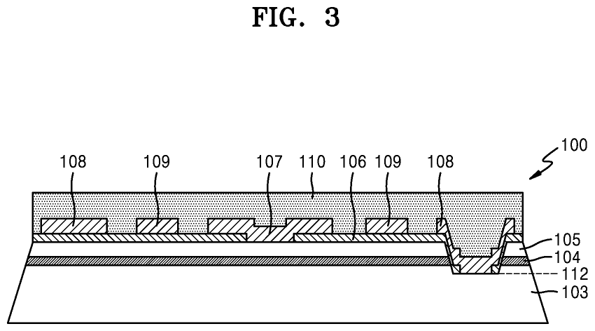

FIG. 3 is a cross-sectional view of the semiconductor device 100 according to an embodiment. The semiconductor device 100 illustrated in FIG. 3 may be the same as the semiconductor device 100 illustrated in FIG. 1, except that the passivation layer 110 covers the first and second electrodes 108 and 107.

Referring to FIG. 3, the passivation layer 110 may cover the first and second electrodes 108 and 107. The passivation layer 110 may prevent physical and chemical damages to the first and second electrodes 108 and 107. In addition, the passivation layer 110 may also protect the side well portion of the light emitting layer 104, by covering the sidewalls of the via holes 112 penetrating the second semiconductor layer 105 and the light emitting layer 104.

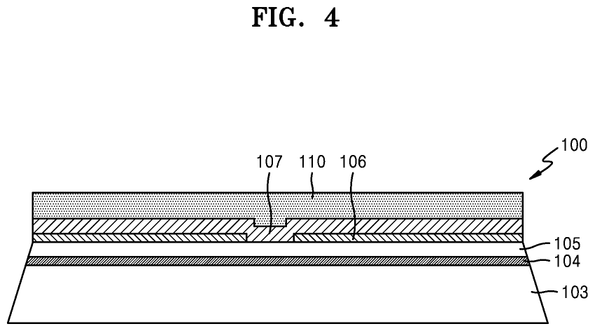

FIG. 4 is a cross-sectional view of the semiconductor device 100 according to an embodiment. In the semiconductor device 100 illustrated in FIG. 4, one second electrode 107 may be on the upper surface of the second semiconductor layer 105. Hereinafter, differences from the above-described embodiments will be mainly described.

Referring to FIG. 4, the semiconductor device 100 may include a semiconductor device layer and the passivation layer 110 on the semiconductor device layer. In this case, the semiconductor device layer may include the first semiconductor layer 103, the light emitting layer 104, the second semiconductor layer 105, and the second electrode 107. Because the first semiconductor layer 103, the light emitting layer 104, and the second semiconductor layer 105 have been described above, descriptions thereof are omitted.

The second electrode 107 may be on the upper surface of the second semiconductor layer 105. The second electrode 107 may be electrically connected to the second semiconductor layer 105. The second electrode 107 may contact the upper surface of the second semiconductor layer 105 exposed via the insulating layer 106. In this case, a portion of the second electrode 107 may further extend from the upper surface of the insulating layer 106 in a lateral direction. When the second semiconductor layer 105 includes a p-type semiconductor layer, the second electrode 107 may include a p-type electrode, and when the second semiconductor layer 105 includes an n-type semiconductor layer, the second electrode 107 may include an n-type electrode.

The passivation layer 110 may be arranged such that the second electrode 107 is covered above the upper surface of the second semiconductor layer 105. In this case, the passivation layer 110 may prevent physical and chemical damages to the second electrode 107.

The passivation layer 110 may include a material that does not chemically react with an electrolyte. In addition, the passivation layer 110 may easily form a pattern, and in a process of fabricating the semiconductor device 100, may include a material, that is not damaged by a solution (for example, a KOH solution or the like) used in a chemical lift-off process. In addition, after the transfer process of the semiconductor device 100, the passivation layer 100 may include a material, that is easily removed for bonding. The passivation layer 110 may include, for example, parylene. However, the embodiment is not limited thereto.

In the above, a case, in which a semiconductor device layer includes a light emitting device, has been described. However, this is merely an example, and in addition, a semiconductor device layer may also constitute one of, for example, a laser device, a detector device, a sensor device, a power device, and a transistor device. In this case, a passivation layer as described above may be on an upper surface of the semiconductor device layer.

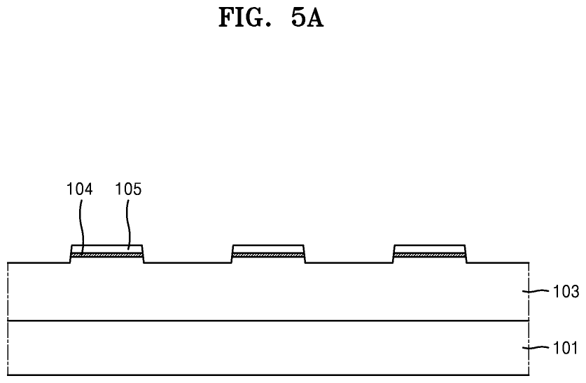

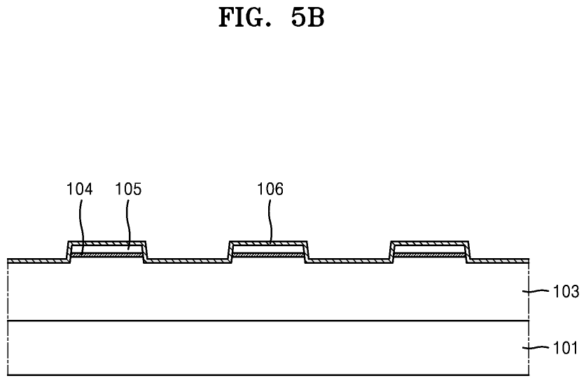

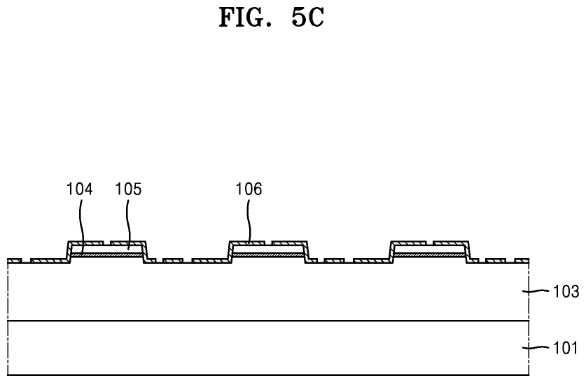

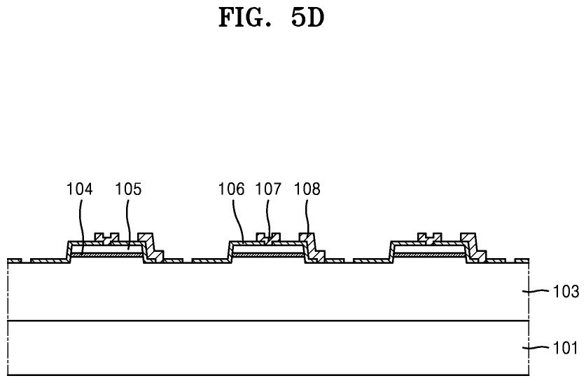

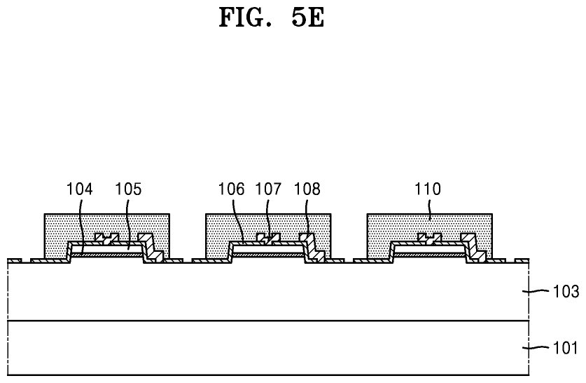

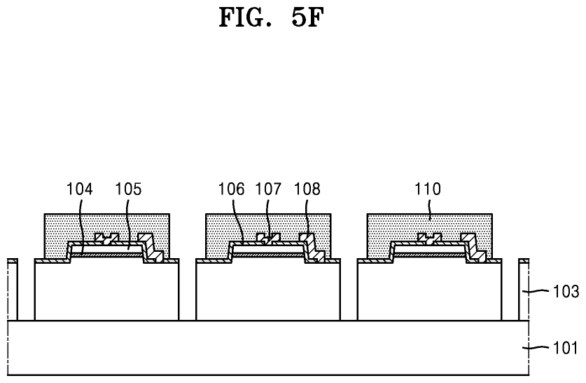

FIGS. 5A, 5B, 5C, 5D, 5E, and 5F are diagrams of a method of fabricating a semiconductor device, according to an embodiment. FIGS. 5A through 5F illustrate in detail a method of fabricating the semiconductor device 100, according to embodiments. In FIGS. 5A through 5F, a process, in which a plurality of semiconductor device layers described above are formed on the semiconductor substrate 100, is illustrated. In the drawings, for convenience, a case, in which three semiconductor device layers are formed on a semiconductor substrate 101, is exemplarily illustrated.

Firstly, referring to FIG. 5A, the first semiconductor layer 103, the light emitting layer 104, and the second semiconductor layer 105 may be sequentially grown on the semiconductor substrate 101. The semiconductor substrate 101 may include, for example, a silicon substrate, but is not limited thereto. On the other hand, a buffer layer for growing a compound semiconductor may be further formed on the semiconductor substrate 101. The buffer layer may include, for example, aluminum nitride, but is not limited thereto.

The first semiconductor layer 103 and the second semiconductor layer 105 may include, for example, a Group III-V or Group II-VI compound semiconductor. The first semiconductor layer 103 and the second semiconductor layer 105 may provide electrons and holes to the light emitting layer 104. To this end, the first semiconductor layer 103 and the second semiconductor layer 105 may be doped with impurities of electrically opposite types. The first semiconductor layer 103 may be doped with impurities of a first conductivity type, and the second semiconductor layer 105 may be doped with impurities of a second conductivity type. For example, the first semiconductor layer 103 may be doped with n-type impurities, and the second semiconductor layer 105 may be doped with p-type impurities. In addition, the first semiconductor layer 103 may also be doped with p-type impurities, and the second semiconductor layer 105 may also be doped with n-type impurities.

The light emitting layer 104 may have a quantum well structure, in which a quantum well is between barriers. The light emitting layer 104 may include only one quantum well, but may include a multi-quantum well (MQW) structure, in which a plurality of quantum wells and a plurality of barriers are alternately arranged.

Next, a plurality of semiconductor device layers may be formed by sequentially etching the second semiconductor layer 105, the light emitting layer 104, and the first semiconductor layer 103. In this case, an etching process may be performed up to a certain depth of the first semiconductor layer 103, and accordingly, side surfaces of the second semiconductor layer 105 and the light emitting layer 104 constituting the semiconductor device layer may be exposed.

Referring to FIG. 5B, the insulating layer 106 may be formed on the plurality of semiconductor device layers formed on the semiconductor substrate 101. The insulating layer 106 may cover the first semiconductor layer 103, the light emitting layer 104, and the second semiconductor layer 105. Next, referring to FIG. 5C, portions of the first and second semiconductor layers 103 and 105 may be exposed by patterning the insulating layer 106.

Referring to FIG. 5D, the first and second electrodes 108 and 107 may be formed, by depositing a conductive metal on an upper surface of a structure illustrated in FIG. 5C, and then patterning the conductive metal. In this case, the first electrode 108 may be connected to the first semiconductor layer 103 exposed via the insulating layer 106, and the second electrode 107 may be connected to the second semiconductor layer 105 exposed via the insulating layer 106. On the other hand, although not illustrated in the drawing, a bonding spread prevention wall including an insulating material may also be further formed between the first electrode 108 and the second electrode 107.

Referring to FIG. 5E, the passivation layer 110 may be formed to cover the structure illustrated in FIG. 5D, and then may be patterned. Accordingly, a plurality of semiconductor devices (100 in FIG. 1) each including the passivation layer 110 may be formed on the semiconductor substrate 101.

The passivation layer 110 may include a material that does not chemically react with an electrolyte. In addition, the passivation layer 110 may easily form a pattern, and may include a material, that is not damaged by a solution (for example, a KOH solution) used in a chemical lift-off process to be described later. In addition, after the transfer process of the semiconductor device 100, the passivation layer 100 may include a material, that is easily removed for bonding. The passivation layer 110 may include, for example, parylene. However, the embodiment is not limited thereto.

Although FIG. 5E exemplarily illustrates a case, in which the passivation layer 110 covers both the first and second electrodes 108 and 107, it may be possible that the passivation layer 110 covers only one of the first and second electrodes 108 and 107.

Referring to FIG. 5F, a plurality of semiconductor devices 100 may be separated by etching the first semiconductor layer 103 between the passivation layers 110 until the semiconductor substrate 101 is exposed in the structure illustrated in FIG. 5E. The separation process of the semiconductor device 100 may be performed by using dry etching or wet etching.

Next, the plurality of semiconductor devices 100 formed on the semiconductor substrate 101 may be separated from the semiconductor substrate 101 by using, for example, a chemical lift-off process. In the chemical lift-off process, a certain solution, for example, a KOH solution, may be used, and the plurality of semiconductor devices 100 may be separated from the semiconductor substrate 101 by using a chemical lift-off process, and may remain in the solution in a flake form. In this case, each semiconductor device 100 may include the passivation layer 110 covering the first and second electrodes 108 and 107, and thus, the first and second electrodes 108 and 107 may be protected from a KOH solution. When the semiconductor devices 100 are separated by using such a chemical separation method, the lower surface of the semiconductor device 100 may have a smooth state.

On the other hand, in the process of fabricating an electronic apparatus to be described later, the first electrode 108 and the second electrode 107 may also have a symmetrical shape to be easily bonded to corresponding electrode pads on an electronic apparatus substrate 150. However, the embodiment is not limited thereto.

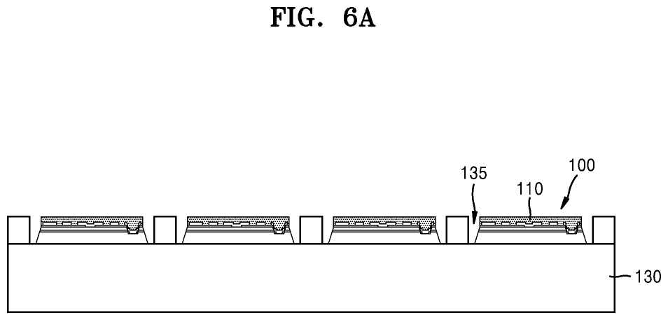

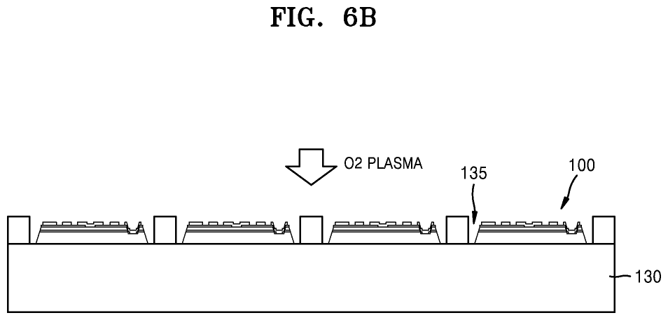

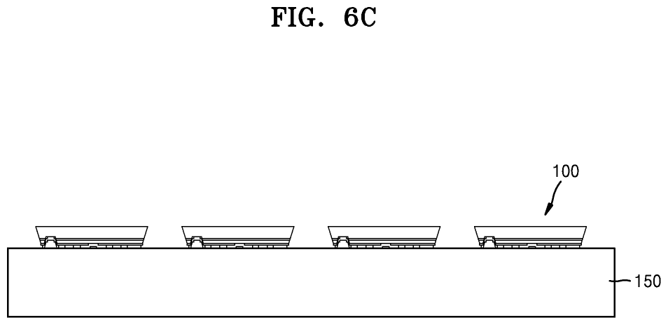

The electronic apparatus may be fabricated by transferring the plurality of semiconductor devices 100 fabricated as described above to the transfer substrate (130 in FIG. 6A), and then transferring the plurality of semiconductor devices 100 transferred to the transfer substrate 130 to the electronic apparatus substrate (150 in FIG. 6C).

FIGS. 6A, 6B, and 6C are diagrams of a method of fabricating an electronic apparatus, according to an embodiment.

Referring to FIG. 6A, after the transfer substrate 130 is prepared, the plurality of semiconductor devices 100 may be transferred into openings 135 of the transfer substrate 130 by using an FSA method. In this case, each of the semiconductor devices 100 may include a semiconductor device layer and the passivation layer 110 on the upper portion of the semiconductor device layer. The semiconductor device layer may constitute a light emitting device fabricated in the process illustrated in FIGS. 5A through 5F. However, this is merely an example, and in addition, the semiconductor device layer may also constitute one of, for example, a laser device, a detector device, a sensor device, a power device, and a transistor device. Each of the semiconductor devices 100 may include the passivation layer 110 covering the first and second electrodes 108 and 107, and accordingly, chemical and physical damages that may occur in the first and second electrodes 108 and 107 of the semiconductor device layer during the transfer process by using an FSA method, may be prevented.

Next, referring to FIG. 6B, the passivation layer 110 on the semiconductor devices 100 may be removed. In this case, the removing of the passivation layer 110 may be performed by, for example, an oxidation (02) plasma treatment. Next, referring to FIG. 6C, the semiconductor device layers transferred to the transfer substrate 130 may be transferred back to the electronic apparatus substrate 150. In this case, the first and second electrodes 108 and 107 of each semiconductor device layer may be bonded to corresponding electrode pads on the electronic apparatus substrate 150, and then, the electronic apparatus may be completed. An electronic apparatus may include, for example, a display apparatus (for example, a micro light emitting diode (LED) display apparatus). However, the disclosure is not limited thereto, and may be applied to various fields.

A semiconductor device may include a passivation layer capable of protecting a horizontal electrode on the semiconductor device layer. Accordingly, in fabricating the electronic apparatus, physical and chemical damages to an electrode that may occur during a transfer process of the semiconductor device by an FSA method, may be prevented. Accordingly, the reliability of the electronic apparatus may be improved, and recycling of the semiconductor device may be implemented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a semiconductor device layer comprising at least one electrode provided at an upper portion thereof; and
a passivation layer at least partially covering the at least one electrode.

2. The semiconductor device of claim 1, wherein the passivation layer comprises a material that does not chemically react with an electrolyte.

3. The semiconductor device of claim 2, wherein the passivation layer comprises parylene.

4. The semiconductor device of claim 1, wherein the semiconductor device layer further comprises:
a first semiconductor layer doped with impurities of a first conductivity type;
a light emitting layer provided on the first semiconductor layer; and
a second semiconductor layer provided on the light emitting layer and doped with impurities of a second conductivity type, and
wherein the at least one electrode is provided on the second semiconductor layer.

5. The semiconductor device of claim 4, wherein the at least one electrode comprises a first electrode electrically connected to the first semiconductor layer and a second electrode electrically connected to the second semiconductor layer.

6. The semiconductor device of claim 5, wherein the passivation layer covers at least one of the first electrode and the second electrode.

7. The semiconductor device of claim 4, wherein the semiconductor device further comprises an insulating layer provided between the second semiconductor layer and the at least one electrode.

8. The semiconductor device of claim 4, wherein the first semiconductor layer comprises an n-type semiconductor layer, and the second semiconductor layer comprises a p-type semiconductor layer.

9. The semiconductor device of claim 4, wherein the first semiconductor layer comprises a p-type semiconductor layer, and the second semiconductor layer comprises an n-type semiconductor layer.

10. The semiconductor device of claim 1, wherein the semiconductor device comprises one of a laser device, a detector device, a sensor device, a power device, and a transistor device.

11. A method of fabricating an electronic apparatus, the method comprising:
forming a plurality of semiconductor device layers on a semiconductor substrate, each of the plurality of semiconductor device layers comprising at least one electrode;
forming a passivation layer on the plurality of semiconductor device layers;
removing a partial region of the passivation layer such that the passivation layer remains on an upper portion of the plurality of semiconductor device layers;
separating the plurality of semiconductor device layers from the semiconductor substrate;
transferring the plurality of semiconductor device layers to a transfer substrate;
removing the passivation layer; and
transferring the plurality of semiconductor device layers on the transfer substrate to an electronic apparatus substrate comprising a driving circuit.

12. The method of claim 11, wherein the separating of the plurality of semiconductor device layers from the semiconductor substrate is performed by immersing the semiconductor substrate in a potassium hydroxide (KOH) solution.

13. The method of claim 11, wherein the plurality of semiconductor device layers are transferred to the transfer substrate by a fluidic self-assembly (FSA) method.

14. The method of claim 11, wherein the passivation layer comprises parylene.

15. The method of claim 14, wherein the passivation layer is removed by using an oxygen (02) plasma treatment.

16. The method of claim 11, wherein the plurality of semiconductor device layers comprise:
a first semiconductor layer doped with impurities of a first conductivity type;
a light emitting layer provided on the first semiconductor layer; and
a second semiconductor layer provided on the light emitting layer and doped with impurities of a second conductivity type, and
wherein the at least one electrode is provided on the second semiconductor layer.

17. The method of claim 16, wherein the at least one electrode comprises a first electrode electrically connected to the first semiconductor layer and a second electrode electrically connected to the second semiconductor layer.

18. The method of claim 17, wherein the passivation layer covers at least one of the first electrode and the second electrode.

19. The method of claim 16, wherein the first semiconductor layer comprises an n-type semiconductor layer and the second semiconductor layer comprises a p-type semiconductor layer.

20. The method of claim 16, wherein the first semiconductor layer comprises a p-type semiconductor layer and the second semiconductor layer comprises an n-type semiconductor layer.
